(19) United States
(12) Patent Application Publication
(10) Pub. No.: US 2016/0098115 A1
(43) Pub. Date: Apr. 7, 2016

(54) DISPLAY WITH INTEGRATED PHOTOVOLTAIC CELL

(71) Applicant: Pixtronix, Inc., San Diego, CA (US)

(72) Inventors: Xia Ren, Tempe, AZ (US); Hung-Chien Lin, Zhubei City (TW); Yu-Hsuan Li, Hsinchu City (TW); Yi Tao, San Jose, CA (US); Jasper Lodewyk Steyn, Campbell, CA (US); Patrick Forrest Brinkley, San Mateo, CA (US)

(21) Appl. No.: 14/591,680

(22) Filed: Jan. 7, 2015

Related U.S. Application Data
(60) Provisional application No. 62/059,379, filed on Oct. 3, 2014.

(51) Int. Cl. G06F 3/044; H01L 31/0232; H01L 31/02

(52) U.S. Cl. CPC G06F 3/044; H01L 31/0201; H01L 31/02325

(57) ABSTRACT

This disclosure provides systems, methods and apparatus for integrating a photovoltaic cell with a display device. One innovative aspect of the subject matter described in this disclosure can be implemented in a display device that includes a first transparent panel and an array of display elements arranged adjacent the first panel. Each display element includes a shutter-based assembly including at least one shutter and at least one actuator capable of translating the shutter to modulate light. The display device also includes a photovoltaic aperture layer arranged adjacent the first panel. The photovoltaic aperture layer includes an array of apertures, each aperture allowing light from a corresponding display element to pass through the photovoltaic aperture layer for display. The display device further includes an array of conductive leads capable of receiving electrical power generated from the photovoltaic aperture layer.

### PRIORITY DATA

This application claims the benefit of priority under 35 U.S.C. §119(e) to U.S. Provisional Application No. 62/059,379 (Attorney Docket No. QUALP270P/145295P1) by Ren et al., titled DISPLAY WITH INTEGRATED PHOTOVOLTAIC CELL and filed on 3 Oct. 2014.

### TECHNICAL FIELD

This disclosure relates generally to displays, and more particularly, to display devices with integrated photovoltaic cells.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

Some display devices can utilize MEMS-based display elements. Such display devices can include, for example, smartphones, e-readers, tablet computers and other mobile or portable devices as well as non-portable devices. As the demand for more versatile display devices increases, and along with it the demand for higher quality displays and smaller, slimmer and sleeker form factors, it has become increasingly challenging to design and incorporate batteries into display devices that meet the power requirements and form factors required to keep pace.

### SUMMARY

The systems, methods and devices of this disclosure each have several innovative aspects, no single one of which is solely responsible for the desirable attributes disclosed herein.

One innovative aspect of the subject matter described in this disclosure can be implemented in a display device that includes a first transparent panel and an array of display elements arranged adjacent the first panel. Each display element includes a shutter-based assembly including at least one shutter and at least one actuator capable of translating the shutter to modulate light. The display device also includes a photovoltaic aperture layer arranged adjacent the first panel. The photovoltaic aperture layer includes an array of apertures, each aperture allowing light from a corresponding display element to pass through the photovoltaic aperture layer for display. The display device further includes an array of conductive leads capable of receiving electrical power generated from the photovoltaic aperture layer.

In some implementations, the array of display elements is arranged on an inner surface of the first panel and the photovoltaic aperture layer is arranged on an outer surface of the first panel. In some other implementations, the photovoltaic aperture layer is arranged on an inner surface of the first panel and the array of display elements is arranged on the photovoltaic aperture layer.

In some implementations, the display device further includes a second panel arranged adjacent an inner surface of the first panel. In some such implementations, the array of display elements is arranged between the first panel and the second panel on an outer surface of the second panel, and the photovoltaic aperture layer is arranged on an outer surface of the first panel. In some other implementations, the array of display elements is arranged between the first panel and the second panel on an outer surface of the second panel, and the photovoltaic aperture layer is arranged on the inner surface of the first panel. In some implementations, the array of display elements is arranged between the first panel and the second panel, each display element being configured to modulate light passage into the first panel from the second panel. In some implementations, the display device further includes a second aperture layer on an outer surface of the second panel. In some implementations, an inner surface of the photovoltaic aperture layer is reflective to the modulated light from the display elements.

In some implementations, the display device further includes a controller configured to analyze power signals received from the photovoltaic aperture layer via the conductive leads and manage power consumption of the device based on an amount or rate of power generated by the photovoltaic aperture layer. In some such implementations, the controller is further configured to modify an operation of the device based on the amount or rate of power generated by the photovoltaic aperture layer.

In some implementations, the display device further includes a controller configured to analyze power signals received from the photovoltaic aperture layer via the conductive leads and determine the occurrences of touches or gestures based on the analyzed power signals.

In some implementations, a ratio of the surface area of the photovoltaic aperture layer not occupied by the apertures to the total surface area occupied by the photovoltaic aperture layer as a whole is greater than or equal to approximately 70%. In some implementations, the photovoltaic aperture layer extends into a bezel region of the device beyond an active portion of the device that includes the display elements.

In some implementations, the display device further includes a processor capable of processing image data and a memory device capable of communicating with the processor. In some implementations, the display device further includes a driver circuit capable of sending at least one signal to the display elements and a controller capable of sending at least a portion of the image data to the driver circuit. In some implementations, the display device further includes an image source module capable of sending the image data to the processor, and the image source module includes at least one of a receiver, transceiver, and transmitter. In some implementations, the display device further includes an input device capable of receiving input data and communicating the input data to the processor.

In another aspect, a display device includes a first transparent panel and an array of shutter-based display means arranged adjacent the first panel. Each shutter-based display means includes at least one shutter and at least one actuation means for translating the shutter to modulate light. The display device also includes a photovoltaic means arranged adjacent the first panel for generating photovoltaic power, the photovoltaic means including an array of apertures, each aperture allowing light from a corresponding shutter-based display means to pass through the photovoltaic means for display. The display device further includes an array of conductive means for receiving photovoltaic power generated from the photovoltaic means.

In some implementations, the display device further includes a controlling means for analyzing power signals received from the photovoltaic means via the conductive means, and managing power consumption of the device based on an amount or rate of power generated by the photovoltaic means. In some implementations, the controlling means is further for modifying an operation of the device based on the amount or rate of power generated by the photovoltaic means. In some implementations, the display device further includes a controlling means for analyzing power signals received from the photovoltaic means via the conductive means, and determining the occurrences of touches or gestures based on the analyzed power signals.

In some implementations, a ratio of the surface area of the photovoltaic means not occupied by the apertures to the total surface area occupied by the photovoltaic means as a whole is greater than or equal to approximately 70%.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual-actuator shutter assembly.

FIG. 3 shows an axonometric view of an example shutter assembly.

FIG. 4A shows a cross-section of a portion of an example multi-layered display panel that includes a photovoltaic aperture layer.

FIG. 4B shows a cross-section of a portion of another example multi-layered display panel that includes a photovoltaic aperture layer.

FIG. 4C shows a cross-section of a portion of another example multi-layered display panel that includes a photovoltaic aperture layer.

FIG. 4D shows a cross-section of a portion of another example multi-layered display panel that includes a photovoltaic aperture layer.

FIG. 5A shows an example photovoltaic aperture layer having rectangular apertures.

FIG. 5B shows an example photovoltaic aperture layer having slot-shaped apertures.

FIG. 6 shows a block diagram of an example host device that includes an array of photovoltaic cells.

FIG. 7 shows a flowchart illustrating a method for managing the power generated by the photovoltaic cells of FIG. 6 and for managing the power consumption of the device of FIG. 6.

FIG. 8 shows a flowchart illustrating a method for determining a touch or gesture using the photovoltaic cells of the device of FIG. 6.

FIGS. 9A and 9B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. Some of the concepts and examples provided in this disclosure are especially applicable to electromechanical systems (EMS) and microelectromechanical (MEMS)-based displays such as the shutter-based displays described herein. However, some implementations also may be applicable to other types of displays, such as liquid crystal displays (LCDs), organic light-emitting diode (OLED) displays, and field emission displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

Various implementations relate generally to displays, including MEMS-based displays, and more particularly to display devices having integrated photovoltaic cells. As described above, a MEMS-based display device generally includes a large number of MEMS-based display elements formed on a substrate and arranged in an array. Each of the MEMS-based display elements can modulate the passage of light through the display element. In some such display devices, the modulated light that passes through the array of display element travels toward an aperture layer that includes an array of corresponding apertures. The light that passes through the apertures forms an image or sequence of images (for example, a video). In various implementations, the aperture layer is formed of, or additionally includes, at least one photovoltaic layer. The photovoltaic layer absorbs incident light (for example, ambient light) and is used to generate electrical power from the absorbed light. In some implementations, the power generated by the photovoltaic layer is used to charge a battery of the display device or to directly power the display or other components of the device. In some implementations, the display device also can distribute power generated by the photovoltaic layer to power an external device electrically coupled with the display device.

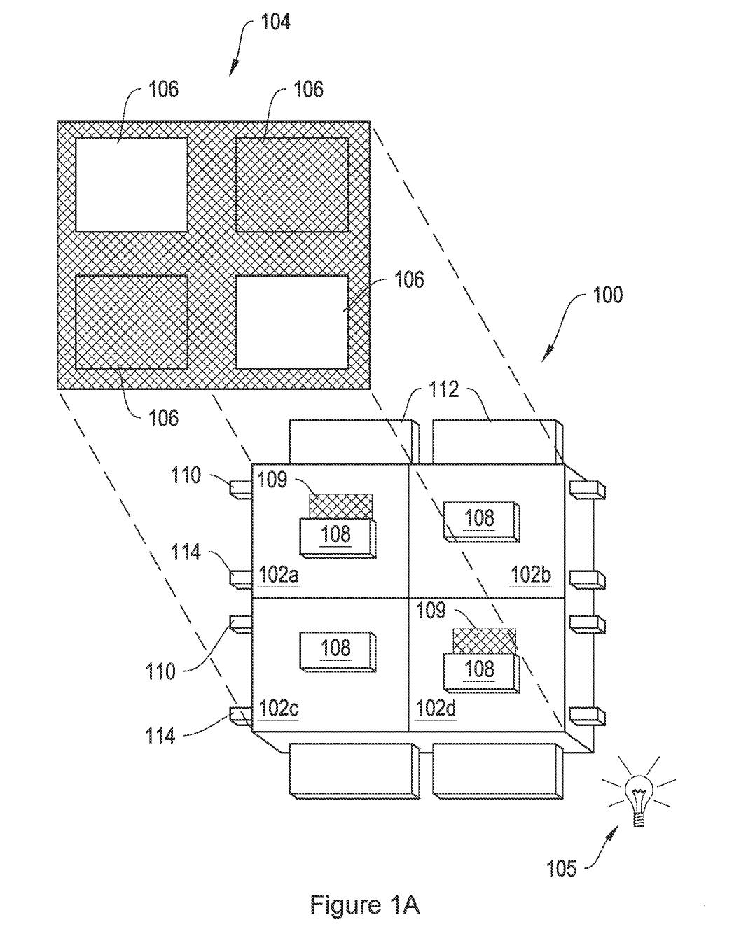

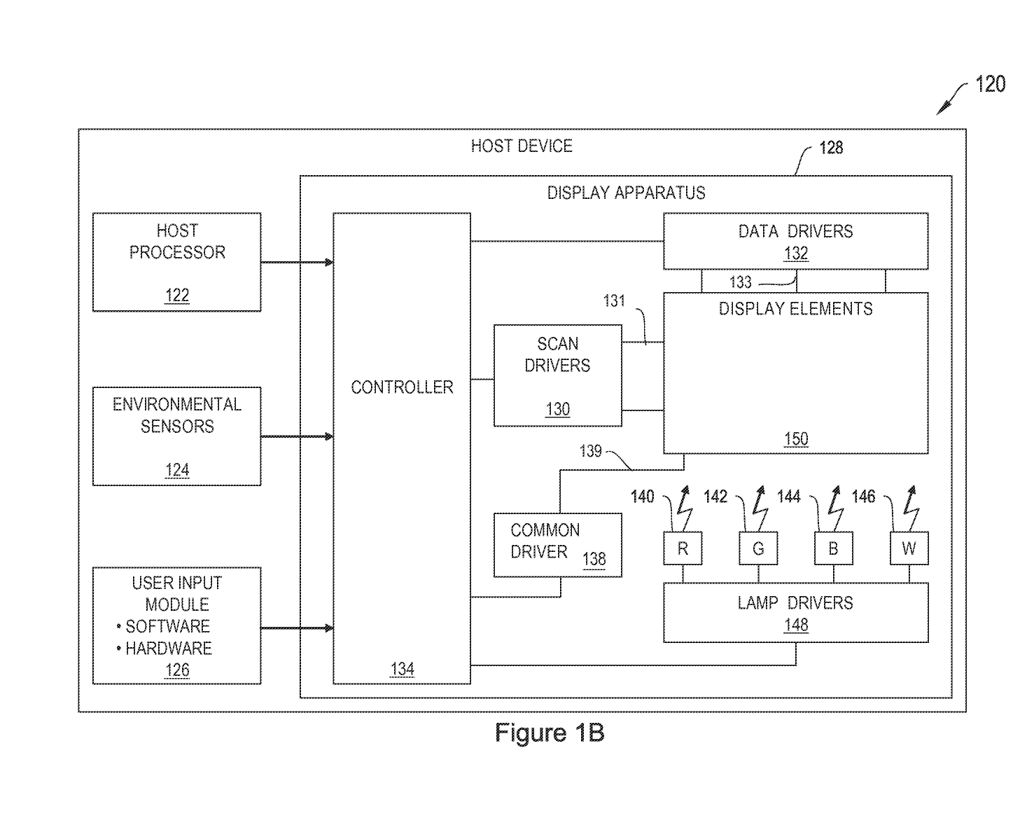

Particular implementations of the subject matter described in this disclosure can be implemented to realize one or more of the following potential advantages. Some implementations efficiently utilize all or substantially all of the available surface area of the aperture layer that does not include apertures to absorb ambient light and generate power from the light. In some such implementations, the ratio of the surface area of the photovoltaic portion of the aperture layer to the total area occupied by the aperture layer (the “footprint”) is greater than or equal to approximately 70%, and in some implementations, greater than or equal to approximately 80%, and in some implementations, greater than or equal to approximately 85%. In other words, in some implementations, the ratio of the area occupied by the apertures of the aperture layer to the total area occupied by the aperture layer (also referred to herein as the “aperture ratio”) is less than or equal to approximately 30%, and in some implementations, less than or equal to approximately 20%, and in some implementations, less than or equal to approximately 15%. Such low aperture ratios can be achieved using, for example, the shutter-based MEMS display elements described herein with respect to FIGS. 1A-5B. This is in stark contrast to aperture ratios achievable using, for example, LCD or LED display elements, which are generally greater than 50%.

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving and/or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for a certain fraction of the image is loaded to the array of display elements 150. For example, the sequence can be implemented to address every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; and/or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

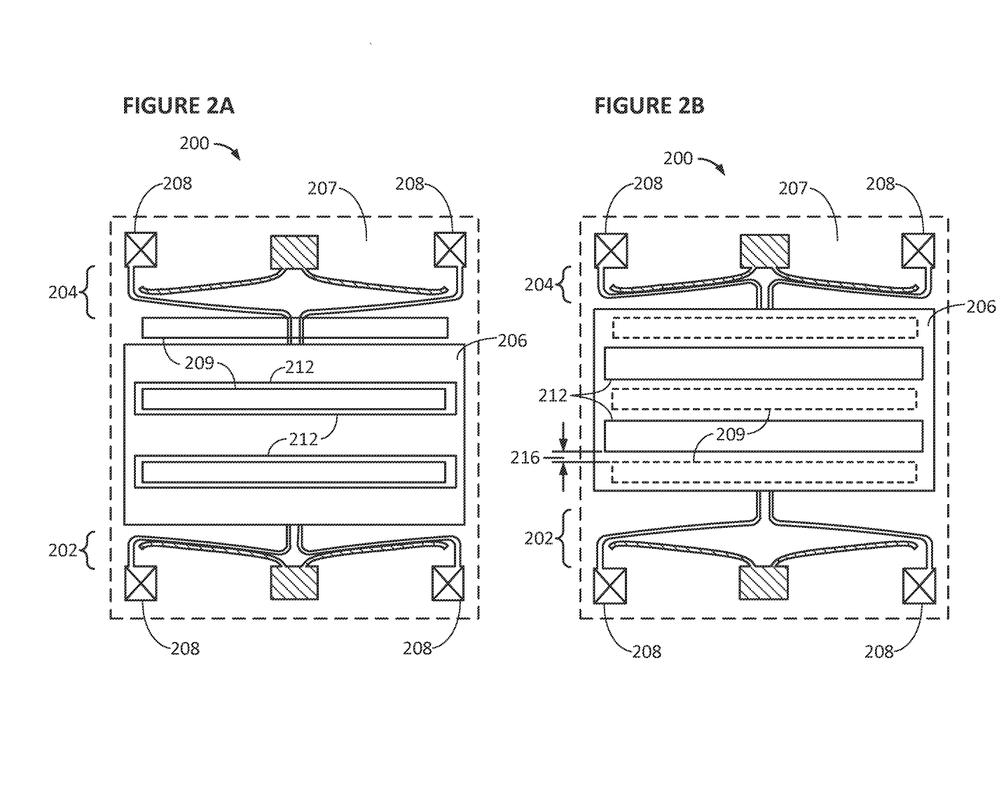

FIGS. 2A and 2B show views of an example dual-actuator shutter assembly 200. The dual-actuator shutter assembly 200, as depicted in FIG. 2A, is in an open state. FIG. 2B shows the dual-actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

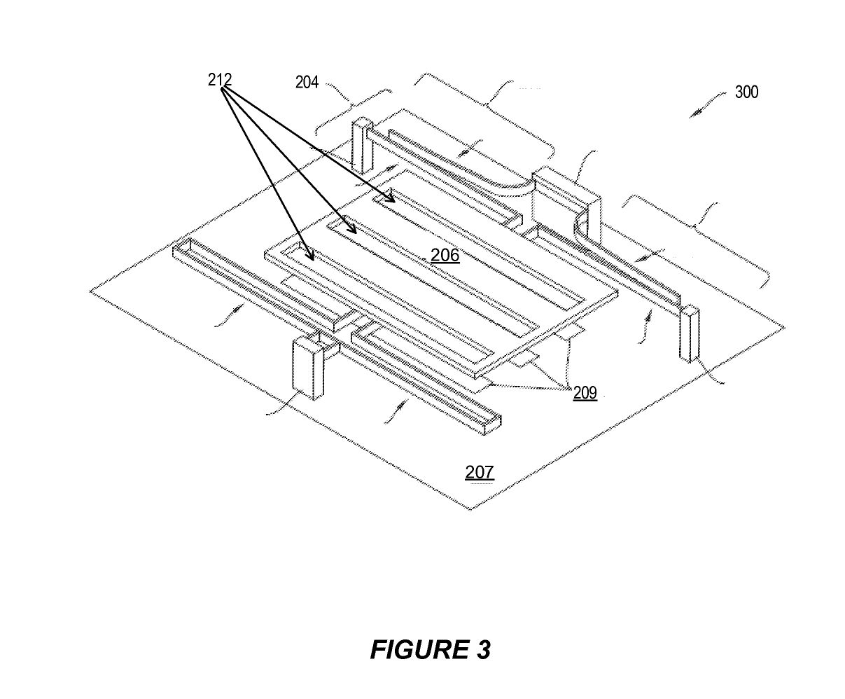

FIG. 3 is an axonometric view of an example shutter assembly 300. The shutter assembly 300 is similar to the shutter assembly 200 shown and described with reference to FIGS. 2A and 2B. However, in contrast to the example dual-actuator shutter assembly 200 of FIGS. 2A and 2B, the shutter assembly 300 shown in FIG. 3 is an example of a single-actuator shutter assembly having a single actuator 204. Additionally, the shutter 206 in the shutter assembly 300 includes three shutter apertures 212 through which light can pass.

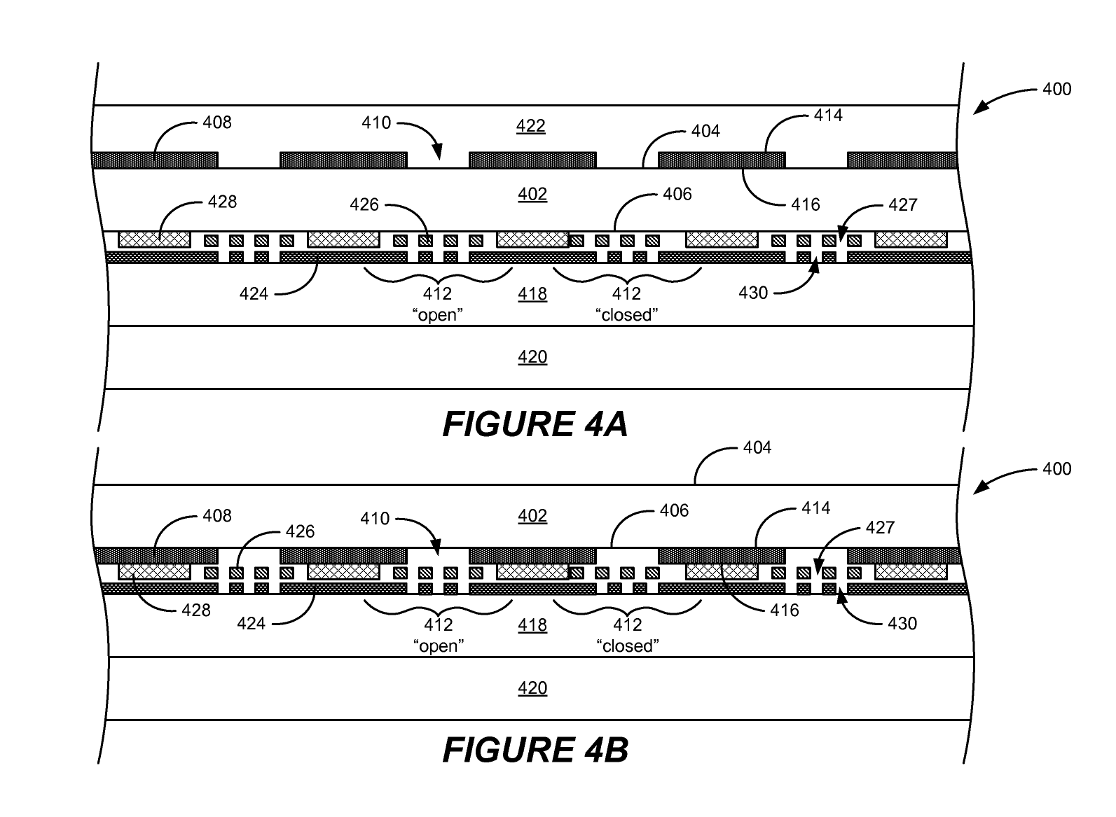

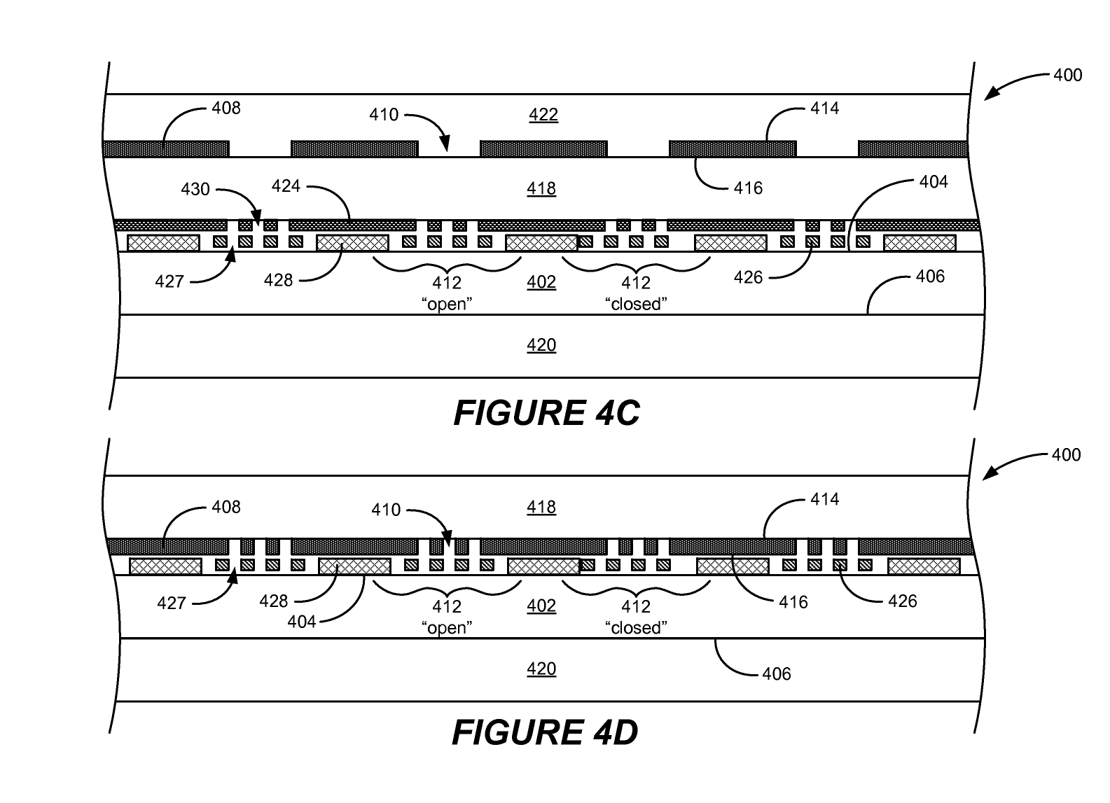

As described above, various implementations relate to display devices having integrated photovoltaic cells. FIG. 4A shows a cross-section of a portion of an example multi-layered display panel 400 that includes a photovoltaic aperture layer 408. The multi-layered display panel 400 includes a first panel (also referred to herein as the “backplane”) 402 having a first (“outer”) surface 404 and a second (“inner”) surface 406 opposite the outer surface 404. The outer surface 404 refers generally to the surface that would face a viewer when the viewer is viewing an image displayed by the display panel 400. The backplane 402 is generally a transparent or translucent panel, at least to frequencies or wavelengths of light in the visible spectrum (hereinafter the terms “transparent” and “translucent” are used interchangeably). In the example implementation of FIG. 4A, a photovoltaic aperture layer 408 is formed on or over the outer surface 404 of the backplane 402. The photovoltaic aperture layer 408 includes an array of apertures 410 through which light can pass.

The backplane 402 is arranged on or over a second transparent panel (also referred to herein as the “intermediate panel”) 418. In some implementations, a second aperture layer 424 (for example, similar to the aperture layer 207 shown and described with reference to FIGS. 2A, 2B and 3) is arranged on or over the intermediate panel 418 between the intermediate panel 418 and the backplane 402. The second aperture layer 424 includes an array of apertures 430. The intermediate panel 418 is arranged on or over a third transparent panel (also referred to herein as the “backlight”) 420 that provides light for the display panel 400. For example, in some implementations light-emitting diodes (LEDs) are configured to emit light into the backlight 420, which then reflects, guides or otherwise propagates the emitting light into the intermediate panel 418. In some implementations, a fourth transparent panel (also referred to herein as the “protective panel”) 422 is arranged on or over the backplane 402. The protective panel 422 protects the outer surface 404 of the backplane 402 as well as any layers or elements, including the photovoltaic aperture layer 408, formed on the outer surface 404 of the backplane 402. In some implementations, each of the backplane 402, the intermediate panel 418, the backlight 420 and the protective panel 422 can be formed of a glass material, a crystal material, a semiconductor material, a plastic material, a blend or stack of such materials, or other suitable materials.

The display panel 400 further includes an array of display elements 412. In some implementations, each of the display elements 412 is a MEMS-based display element. In some such implementations, each display element 412 includes a shutter-based assembly, such as or similar to the shutter assemblies 200 or 300 shown and described with reference to FIGS. 2A, 2B and 3. More specifically, each of the display elements 412 includes a translatable shutter 426 (such as or similar to the shutter 206 shown and described with reference to FIGS. 2A, 2B and 3) and at least one actuator 428 (such as or similar to the actuators 202 or 204 shown and described with reference to FIGS. 2A, 2B and 3). In some implementations, each display element 412 includes two actuators 428, each on opposing sides of the corresponding shutter 426 (such as in the dual-actuator shutter assembly 200 of FIGS. 2A and 2B). In some other implementations, each display element 412 can include a single actuator 428 (such as in the shutter assembly 300 of FIG. 3).

In the example implementation of FIG. 4A, the shutters 426 and the actuators 428 are formed or otherwise arranged on or over the inner surface 406 of the backplane 402. As described above, each of the actuators 428, and more generally each of the display elements 412, can be individually-addressable (or “independently-actuatable”) by one or more display drivers (for example, the scan and data drivers 130 and 132 described above with respect to FIG. 1B). Each actuator 428 is configured to cause, responsive to one or more signals from the display drivers, the corresponding shutter 426 to move from a closed position to an open position and vice versa, as shown in FIG. 4A. More specifically, when the shutter 426 is in the closed position, the light-blocking portions of the shutter 426 block the light emitted through the corresponding aperture 430 in the second aperture layer 424. When the shutter 426 is in the open position, the light-passing portions 427 of the shutter 426 (for example, similar to the slots or apertures 212 of FIGS. 2A, 2B and 3) permit light to pass through to the backplane 402.

In some implementations, the shutters 426, the actuators 428 and the electrically conductive leads or other elements associated with the shutters and the actuators (all also referred to herein collectively as the “MEMS layer”) are formed via one or more metal depositing or growing (“metallization”) processes. The shutters 426, the actuators 428 and the electrically conductive leads or other elements of the MEMS layer can be formed of, for example, one or more metals, metallic alloys, or suitable inorganic conductive materials. The second aperture layer 424 also can be formed using one or more metallization or other layer deposition processes including, where appropriate, inorganic thin film deposition processes, organic thin film deposition processes, flat panel display manufacturing processes or semiconductor manufacturing processes.

Referring back to the first photovoltaic aperture layer 408, one purpose of the photovoltaic aperture layer 408 is to provide a desired contrast. For example, the photovoltaic aperture layer 408 can provide a dark or black viewing surface when the display elements 412 of the display are not transmitting or passing light in order to provide the desired contrast. In some implementations, another purpose or function of the photovoltaic aperture layer 408 is to restrict a portion of the light passing through the display elements 412. For example, in such implementations, only the light transmitted through the display elements 412 having a limited angle relative to a line normal to the surface 404 is able to pass through the apertures 410. In this way, the light passing through the apertures 410 of the photovoltaic aperture layer 408 is more directional. In some implementations, the photovoltaic aperture layer 408 also may function to limit the amount of ambient light that may enter the display panel 400.

The photovoltaic aperture layer 408 is formed of a material that exhibits the photovoltaic effect. For example, the photovoltaic aperture layer 408 can be formed of one or more of monocrystalline silicon, polycrystalline silicon, amorphous silicon, cadmium telluride, copper indium gallium selenide (CIGS) or copper indium gallium sulfide, among other suitable materials. The photovoltaic aperture layer 408, although sometimes referred to herein as a single photovoltaic layer, generally includes at least two layers. For example, the photovoltaic aperture layer 408 can include a p-type semiconducting layer and an n-type semiconducting layer formed adjacent one another. Each of the p-type semiconducting layer and the n-type semiconducting layer can be electrically connected to corresponding conductive leads (also referred to herein as interconnects, traces, busbars, wires or electrodes) to separate the charge (in the form of electron-hole pairs) created when light is absorbed into the photovoltaic aperture layer 408. In some implementations, the photovoltaic aperture layer 408 is a single junction photovoltaic cell. A single junction photovoltaic cell includes one p-type semiconducting layer and one n-type semiconducting layer; the interface between these two layers is referred to as a p-n junction. In some implementations, the photovoltaic aperture layer 408 can additionally include an intrinsic semiconducting layer between the n-type semiconducting layer and the p-type semiconducting layer. This type of junction is generally referred to as a “p-i-n” or “pin” junction (where the “i” represents the intrinsic semiconducting layer). In some other implementations, the photovoltaic aperture layer 408 can be a multi junction photovoltaic cell. A multi junction photovoltaic cell includes multiple p-n or p-i-n junctions; that is, multiple p-type semiconducting layers interlaced with multiple n-type semiconducting layers.

In some other implementations, the photovoltaic aperture layer 408 is a multi-layered film structure that includes a photovoltaic layer as well as one or more additional layers. For example, in some multi-layered implementations, the photovoltaic aperture layer 408 can include both a photovoltaic layer as described above as well as an additional “dark” layer. For example, the additional dark layer of the photovoltaic aperture layer 408 can be positioned under the photovoltaic layer between the photovoltaic layer and the backplane 402. The dark layer can be formed of a dark material such as carbon (C) or a carbon-based material, among other suitable materials. For example, the dark layer can provide a darker or blacker viewing surface when the display elements 412 of the display are not transmitting or passing light in order to provide the desired contrast. However, a dark layer is not included or necessary in other implementations, for example, when the photovoltaic layer is sufficiently dark to provide the desired contrast.

In some implementations, one or more layers of the photovoltaic aperture layer 408 are spun onto the outer surface 404 (or other surfaces as described below with reference to FIGS. 4B-4D) of the backplane 402. For example, one or more layers of the photovoltaic aperture layer 408 can be spun on using a spin-coating process. In some such implementations, the apertures 410 in the photovoltaic aperture layer 408 are formed by etching or otherwise removing portions of the spin-on coating. For example, in implementations in which the spin-on coating is formed of a photoresist material, the apertures 410 can be removed using photolithography processes. In some other implementations, one or more layers of the photovoltaic aperture layer 408, including the photovoltaic layer or dark layer, can be deposited, grown or otherwise formed via slit coating, slot die coating, physical vapor deposition (PVD), chemical vapor deposition (CVD) or other suitable techniques including various semiconductor manufacturing processes.

In some implementations, each aperture 410 is associated with a respective display element 412 and allows light from the respective display element to pass. In some implementations, all or substantially all of the viewable area of the outer surface 404 of the backplane 402 is covered by the photovoltaic aperture layer 408 except for those portions where there is an aperture 410. In some implementations, the ratio of the surface area occupied by the apertures 410 of the photovoltaic aperture layer 408 to the total area occupied by the photovoltaic aperture layer 408 (again, also referred to herein as the “aperture ratio”) is less than approximately 30%, and in some implementations less than approximately 20%, and in some implementations less than approximately 15%. As described above, in some implementations the viewable surface 414 (facing the viewer) of the photovoltaic aperture layer 408 is a black light-absorbing surface. In some implementations, the inner surface 416 (facing the display elements 412) of the photovoltaic aperture layer 408 is a light-reflecting surface to facilitate light recycling back into the intermediate panel 418 or backlight 420.

In some implementations, an area surrounding some or all of the displayable active portion of the backplane 402 also is covered by a photovoltaic layer. The active portion refers generally to the area of the backplane 402 where there are display elements 412, and thus, the area from which an image or video can be displayed. For example, a bezel region around the displayable active portion of the backplane 402, and in some instances around the backplane 402 itself, also can be covered by a photovoltaic layer. In some such implementations, the photovoltaic aperture layer 408 itself can extend beyond the displayable active portion throughout some or all of the bezel region. Extending the photovoltaic aperture layer 408 into the bezel region increases the light-absorbing surface area of the photovoltaic aperture layer 408 to maximize the power-generation capabilities of the device incorporating the display panel 400. In some other implementations, a photovoltaic layer separate from the photovoltaic aperture layer 408 can be formed around the displayable active portion of the display as well as in areas around or outside of the backplane 402, such as in a bezel region. Additionally, in some implementations, the photovoltaic aperture layer 408 can be formed over a reflective layer. In such implementations, the reflective layer can increase the efficiency of the photovoltaic cell by reflecting incident light that may otherwise pass through the photovoltaic aperture layer without being absorbed and converted to electron-hole pairs.

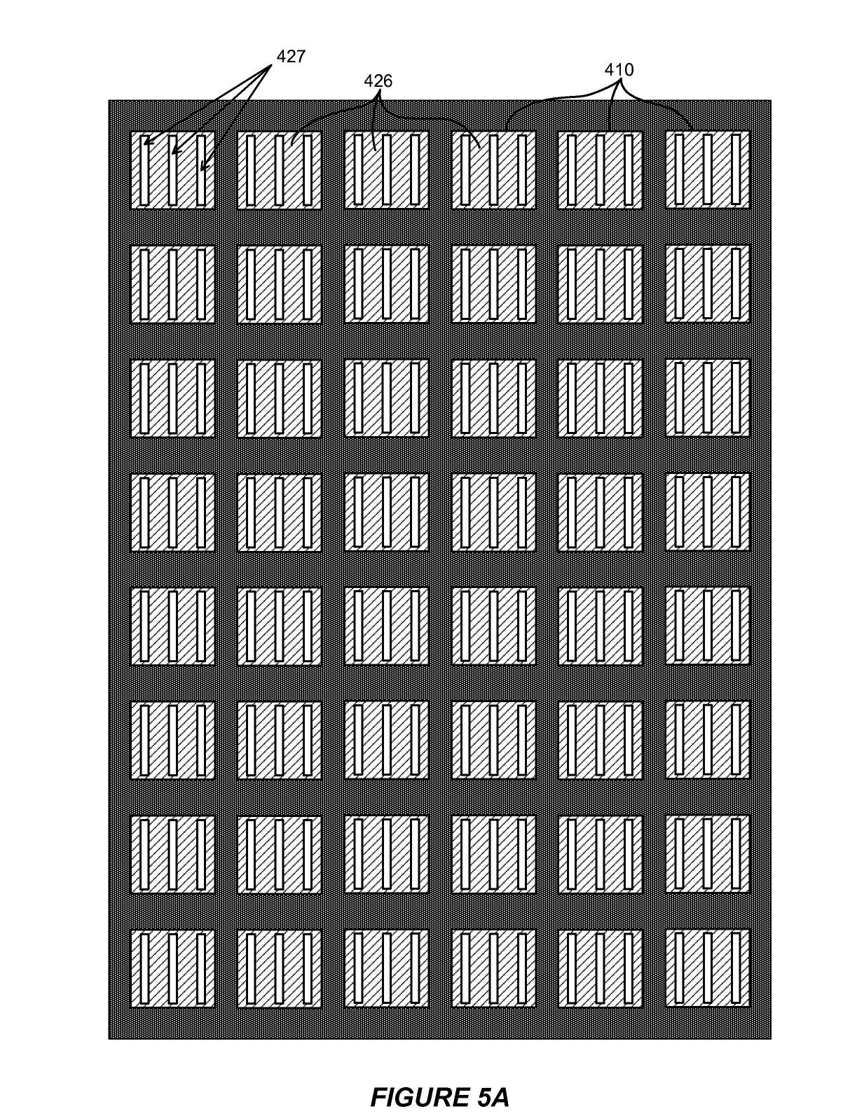

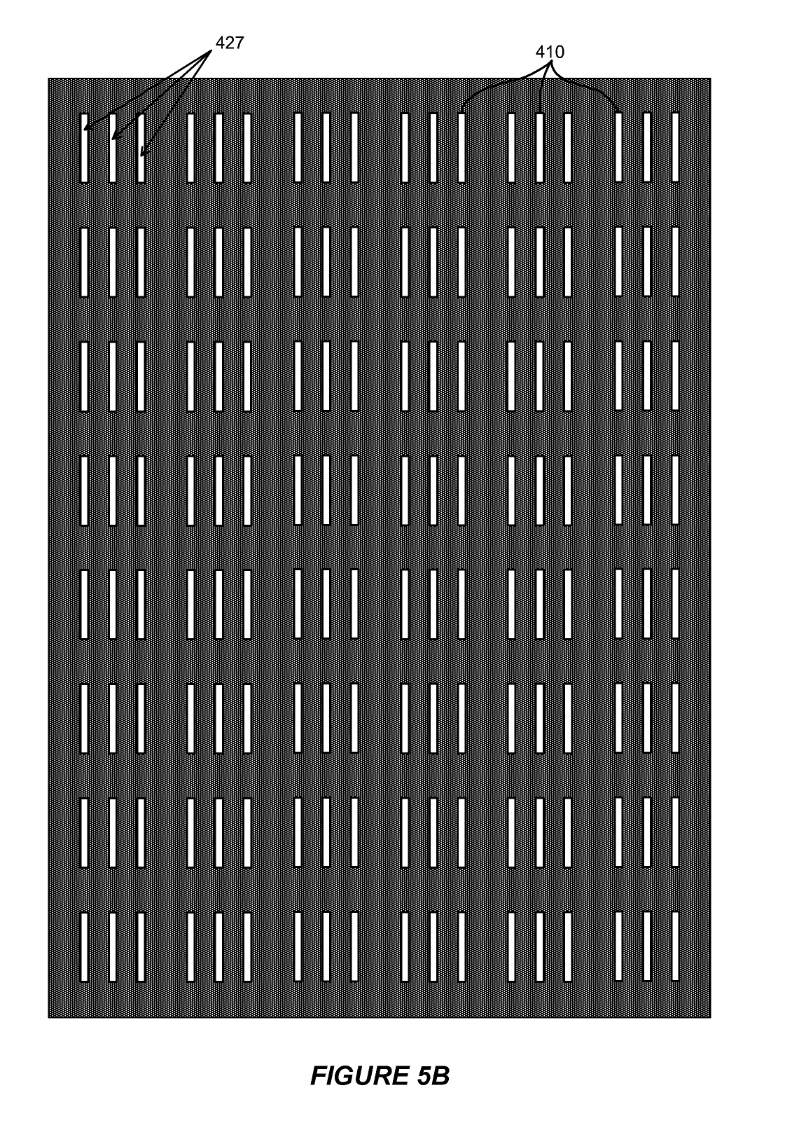

FIG. 5A shows an example photovoltaic aperture layer 408 having rectangular apertures 410. The photovoltaic aperture layer 408 of FIG. 5A is shown arranged over an example MEMS layer that includes shutters 426 having slot-shaped light passing portions 427 as described above. As shown, each of the apertures 410 in FIG. 5A encompasses an area roughly the size of a display element 412. FIG. 5B shows an example photovoltaic aperture layer 408 having slot-shaped apertures 410. In FIG. 5B, the size, aspect ratio and shape of the apertures 410 can be the same as or similar to the size, aspect ratio and shape of the slots 427 in the shutters 426. For example, it may be desirable that the apertures 410 be slightly larger than the corresponding slots 427. As shown, the photovoltaic aperture layer 408 in FIG. 5B achieves a significantly smaller aperture ratio than the photovoltaic aperture layer 408 shown in FIG. 5A, and thus, provides greater light-absorbing surface area for photovoltaic power generation. While matching the shape and size of the apertures 410 to the corresponding slots 427 in the shutters 426 can be advantageous in some implementations to maximize the light-absorbing surface area of the photovoltaic aperture layer 408, in some other implementations, the apertures 410 can have different shapes and sizes. For example, in some other implementations, the apertures 410 can have circular, oval, or other shapes. Generally, it may be desirable for the size and shape of the apertures 410 in the photovoltaic aperture layer 408 to correspond to the size and shape of the shutter slots or openings 427 associated with the underlying display elements.

While in the foregoing implementations, the photovoltaic aperture layer 408 has been described as being formed or arranged on the outer surface 404 of the backplane 402, in some other implementations, other arrangements or configurations can be advantageous. FIG. 4B shows a cross-section of a portion of another example multi-layered display panel 400 that includes a photovoltaic aperture layer 408. In contrast to the implementations shown and described with reference to FIG. 4A, the photovoltaic aperture layer 408 of FIG. 4B is formed on or over the inner surface 406 of the backplane 402. More specifically, the photovoltaic aperture layer 408 of FIG. 4B is formed or arranged between the inner surface 406 and the MEMS layer that includes the shutters 426 and the actuators 428 of the display elements 412. In some such implementations, the MEMS layer, including the shutters 426 and actuators 428, is formed on or over the photovoltaic aperture layer 408.

FIG. 4C shows a cross-section of a portion of another example multi-layered display panel 400 that includes a photovoltaic aperture layer 408. In contrast to the implementations shown and described with reference to FIGS. 4A and 4B, the backplane 402 in the example implementation of FIG. 4C is arranged under the intermediate panel 418 between the intermediate panel 418 and the backlight 420. In this implementation, the photovoltaic aperture layer 408 is formed on an outer surface of the intermediate panel 418. In this implementation, a second aperture layer 424 can be included and can be formed on the inner surface of the intermediate panel while the MEMS layer, including the shutters 426 and actuators 428, can be formed on the outer surface 404 of the backplane 402.

FIG. 4D shows a cross-section of a portion of another example multi-layered display panel 400 that includes a photovoltaic aperture layer 408. Like the implementation shown and described with reference to FIG. 4C, the backplane 402 in the example implementation of FIG. 4D is arranged under the intermediate panel 418 between the intermediate panel 418 and the backlight 420. However, unlike the implementation shown in FIG. 4C, in the implementation of FIG. 4D, the photovoltaic aperture layer 408 is formed on an inner surface of the intermediate panel 418. Additionally, the apertures 410 are in the form of slots similar to the implementation shown and described with reference to FIG. 5B. In this implementation, a second aperture layer 424 is not included because, for example, the photovoltaic aperture layer 408 also serves the function of the second aperture layer 424 described above.

Additionally, in some implementations the photovoltaic aperture layer 408 can be formed such that it is divided into an array of photovoltaic cells. For example, each photovoltaic cell can have a rectangular footprint and be sized and arranged to overlie a corresponding display element 412 or a sub-array of the display elements 412 of the entire display. For example, each photovoltaic cell can overlie a sub-array of tens, hundreds, thousands, tens of thousands, or hundreds of thousands or more display elements 412. Each of the photovoltaic cells is capable of generating power from light. Each of the photovoltaic cells also is electrically connected to route the power generated from the cell via associated conductive leads, electrodes, bus bars, interconnects or other electrical lines to, for example, a controller, a battery, the display elements of the display panel, or various other electrical components internal or external to a host device that includes the display panel 400 and the photovoltaic aperture layer 408. It can be beneficial to form the photovoltaic aperture layer 408 into an array of cells to improve power generation. For example, often a display will be partially shaded during use. Dividing the photovoltaic aperture layer 408 into an array of individual photovoltaic cells can increase power generation when portions of the display are shaded.

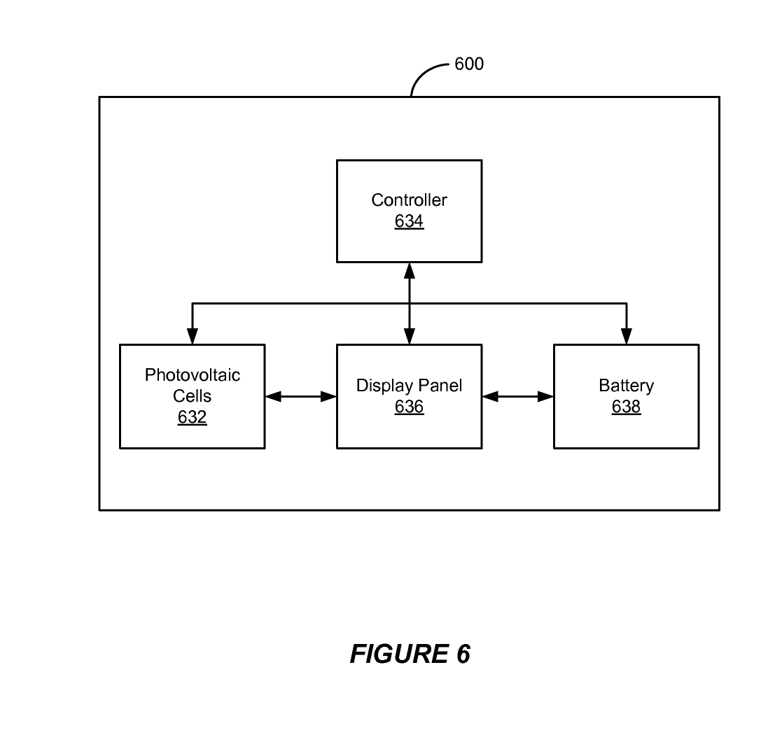

Some implementations also relate to managing the power generated by the photovoltaic aperture layer 408. FIG. 6 shows a block diagram of an example host device 600 that includes an array of photovoltaic cells 632. For example, the array of photovoltaic cells 632 can include any suitable or desired number of individual photovoltaic cells as described above. The host device 600 also includes a controller 634, a display panel 636, and a battery 638 for storing energy for use by the device 600. In some implementations, the display panel 636 is the same as or is similar to the display panels 400 described above with reference to FIGS. 4A-4D and 5A-5B. In some implementations, the photovoltaic cell 632 can be formed as an integrated part of the display panel 636. For example, the photovoltaic cell 632 can include a photovoltaic aperture layer 408 as described above.

The controller 634 can include any suitable number or combination of controllers, microcontrollers, processors, logic devices, circuits, other electrical components or other hardware, firmware or software for managing the power generated by the photovoltaic aperture layer 408. In some implementations, the controller 634 is the same controller that manages the display drivers that drive the display elements of the display panel 636 (for example, the same as or similar to the controller 134 described with reference to FIG. 1B). In some other implementations, the controller 634 is a different controller than that which manages the display drivers that drive the display elements of the display panel 636. In some such implementations, the controller 634 is in communication with the controller (for example, the controller 134 described with reference to FIG. 1B) that manages the display drivers.

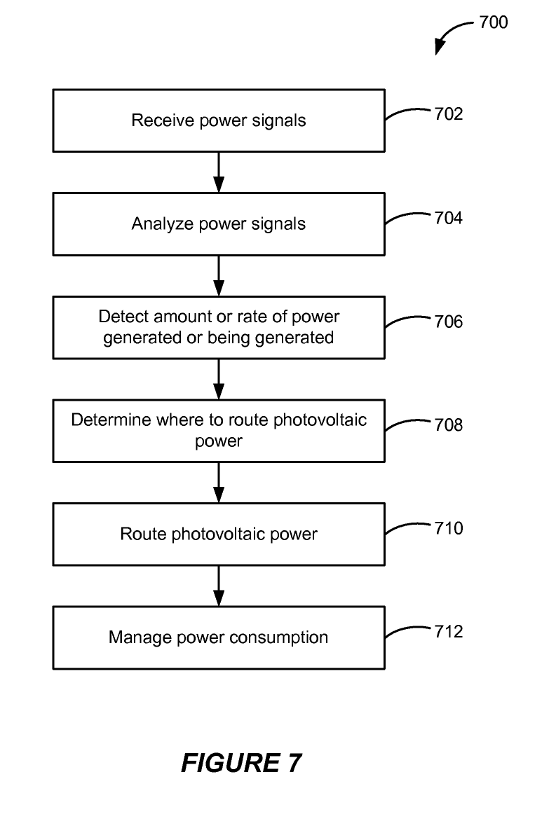

FIG. 7 shows a flowchart illustrating a method 700 for managing the power generated by the photovoltaic cells 632 of FIG. 6 and for managing the power consumption of the device 600 of FIG. 6. In some implementations, the method 700 begins in block 702 with the controller 634 receiving power signals generated by the photovoltaic cells 632. In block 704, the controller 634 analyzes the power signals. In block 706, the controller 634 detects an amount or rate of power generated or being generated by the photovoltaic cells 632. In block 708, the controller 634 determines, based on the amount or rate of power detected in block 706, where to route the power generated by the photovoltaic cells 632, for example, to the battery 638 for storage or to other elements of the device 600. The controller then routes the power generated by the photovoltaic cells 632 in block 710 based on the determination in block 708. For example, if the amount or rate of power detected in block 706 is above a threshold value, then the controller 634 can determine in block 708 to route the power to both the battery 638 as well as the display panel 636, other elements within the device 600, or a device external to but electrically connected with the device 600. In some implementations, if the amount or rate of power detected in block 706 is below the threshold value, then the controller 634 can determine in block 708 to route the power to the battery 638 only.

In some implementations, the determination made in block 708 also is based on current operating conditions or a state of the device 600. For example, if the controller 634 determines in block 708 that the power consumption of the device 600 is above a threshold value, then the controller 634 can route, in block 710, the power to both the battery 638 as well as the display panel 636, other elements within the device 600, or a device external but electrically connected with the device 600. Conversely, if the controller 634 determines in block 708 that the power consumption of the device 600 is below a threshold value, then the controller 634 can route, in block 710, the power to the battery 638 only. As another example, if the controller 634 determines that the battery 638 is already charged to its full capacity or is within a threshold of its full capacity, the controller 634 can cause the power generated by the photovoltaic cells 632 to be routed, in block 710, to the display panel 636, other elements within the device 600, or a device external but electrically connected with the device 600 regardless of the whether the amount or rate of power detected in block 706 is above or below the threshold value.

In some implementations, in block 712, the controller 634 adaptively manages the power consumption of the device 600. For example, in some implementations, the controller 634 causes the display drivers to increase the brightness (or “luminosity”) of the display elements of the display panel 636 when the amount or rate of power detected in block 706 reaches or exceeds a threshold level. Conversely, in some implementations, the controller 634 causes the display drivers to decrease the brightness of the display elements of the display panel 636 when the amount or rate of power detected in block 706 falls below a threshold level. Additionally or alternatively, in some implementations, the controller 634 disables, delays or prevents a hibernation or “sleep” mode of the device 600 when the amount or rate of power detected in block 706 reaches or exceeds a threshold level. Additionally or alternatively, in some implementations, the controller 634 turns off or disables one or more wireless interfaces, reduces or disables certain operations or features of the device, or otherwise reduces power consumption of the device 600 when the amount or rate of power detected in block 706 falls or remains below a threshold level. Conversely, in some implementations, the controller 634 turns on or enables one or more wireless interfaces, turns on or enables certain operations or features of the device, or otherwise increases power consumption of the device 600 when the amount or rate of power detected in block 706 reaches or exceeds a threshold level.

In some implementations, the controller 634 also can receive and use input from a dedicated ambient light sensor to make the determination in block 708 or to manage the power consumption in block 712. Additionally, in some implementations the controller 634 can determine an orientation, a change in orientation, or determine a movement of the device 600 based on the analysis of the power signals in block 704 or the amount or rate of power detected in block 706 from the respective photovoltaic cells 632 or groups of photovoltaic cells 632.

As described above, in some implementations the photovoltaic aperture layer 408 can be formed such that it is divided into an array of photovoltaic cells. In some implementations, the photovoltaic cells can be integrated with a touch or gesture recognition system. Referring to the device 600 of FIG. 6, in some such implementations, the controller 634 can determine when a touch or gesture (for example, by a finger or stylus) has occurred based on the detection of a substantial decrease in the amount or rate of power generated or being generated by a particular one of the photovoltaic cells 632 or group of photovoltaic cells 632.

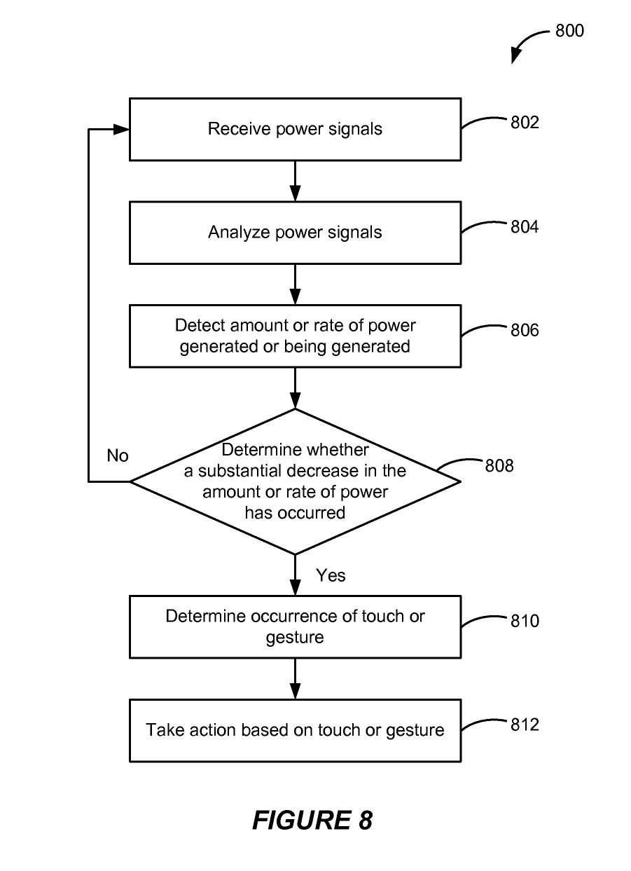

FIG. 8 shows a flowchart illustrating a method 800 for determining a touch or gesture using the photovoltaic cells 632 of the device 600 of FIG. 6. In some implementations, the method 800 begins in block 802 with the controller 634 receiving power signals generated by respective ones or respective groups of the photovoltaic cells 632. In block 804, the controller 634 analyzes the power signals. In block 806, the controller 636 detects an amount or rate of power generated or being generated by the respective ones or respective groups of the photovoltaic cells 632. In block 808, the controller 634 determines whether there is a substantial decrease, and particularly a substantial decrease in a short duration of time, in the amount or rate of power generated or being generated by the respective ones or respective groups of the photovoltaic cells 632. If the controller 634 determines in block 808 that there is a substantial decrease in in the amount or rate of power generated or being generated by the respective ones or respective groups of the photovoltaic cells 632, the controller determines, in block 810, that a touch or gesture has occurred on or over these respective ones or groups of photovoltaic cells 632. In block 812, the controller 634 can take an action with respect to the operations of the device 600 based on the touch or gesture.

In some other implementations in which capacitive or resistive touchscreen technology is integrated with the display panel 636 of the device 600, some of the conductive leads, electrodes, bus bars, interconnects or other electrical lines used to route power generated by the photovoltaic cells 632 to the controller 634 also can serve as electrodes for recognizing touches or gestures via capacitive or resistive sensing techniques. For example, when a touch or gesture occurs over respective ones or groups of the electrodes, the resistance (or impedance) or capacitance associated with these electrodes can change causing a change in the power signals received and detected by the controller 634. The controller 634 can then determine that a touch or gesture has occurred and take an action with respect to the operations of the device 600 based on the touch or gesture.

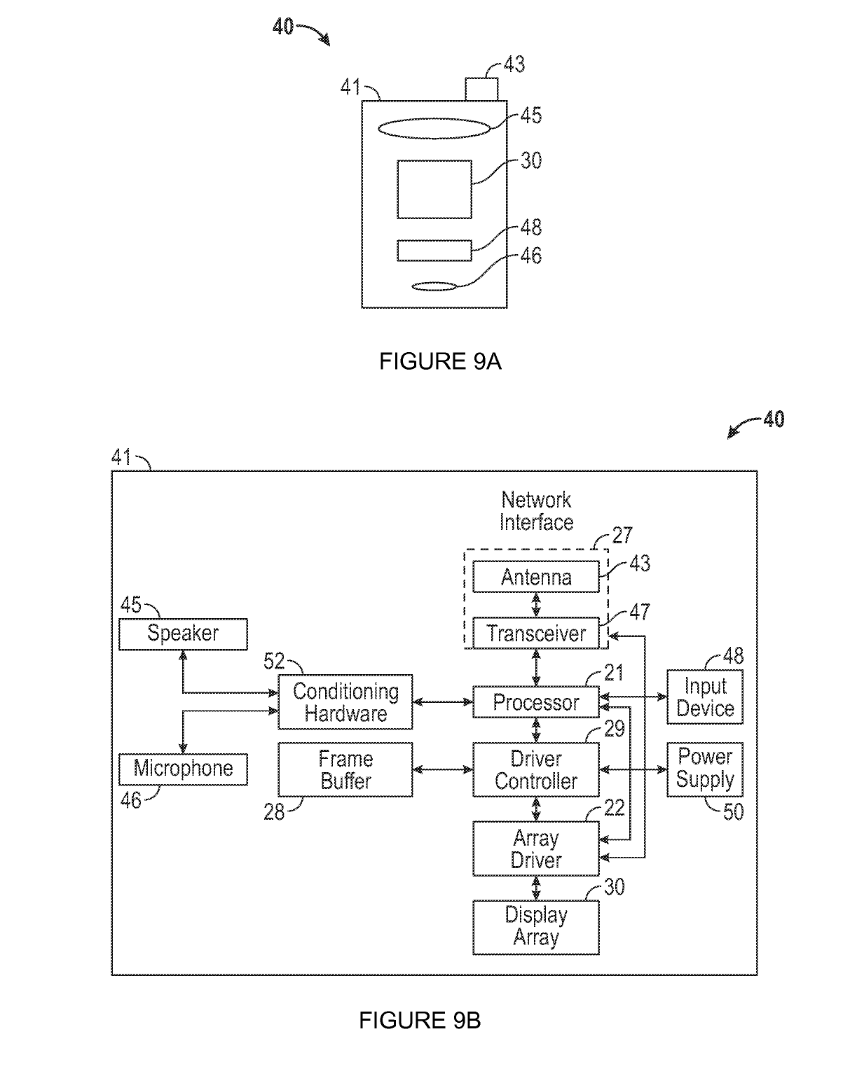

FIGS. 9A and 9B show system block diagrams of an example display device 40 that includes a plurality of display elements. For example, the display elements can be MEMS-based display elements such as the shutter-based display elements described above. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 can include a mechanical light modulator-based display, such as the shutter-based assembly displays described herein. In some other implementations, the teachings herein can be applied to a display 30 of a different display type, such as a plasma display, an electroluminescent (EL) display, an OLED display, a super twisted nematic (STN) display, an LCD display, a thin-film transistor (TFT) LCD display.

The components of the display device 40 are schematically illustrated in FIG. 9B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 9A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Some designs for implementing dithering elements can be produced in software. Some dithering processes can be implementing using software. In either case, if implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display device comprising:
a first transparent panel;
an array of display elements arranged adjacent the first panel, each display element including a shutter-based assembly including at least one shutter and at least one actuator capable of translating the shutter to modulate light;
a photovoltaic aperture layer arranged adjacent the first panel, the photovoltaic aperture layer including an array of apertures, each aperture allowing light from a corresponding display element to pass through the photovoltaic aperture layer for display; and
an array of conductive leads capable of receiving electrical power generated from the photovoltaic aperture layer.

2. The display device of claim 1, wherein:
the array of display elements is arranged on an inner surface of the first panel; and
the photovoltaic aperture layer is arranged on an outer surface of the first panel.

3. The display device of claim 1, wherein:
the photovoltaic aperture layer is arranged on an inner surface of the first panel; and
the array of display elements is arranged on the photovoltaic aperture layer.

4. The display device of claim 1, further comprising a second panel arranged adjacent to an inner surface of the first panel.

5. The display device of claim 4, wherein:
the array of display elements is arranged between the first panel and the second panel on an outer surface of the second panel; and
the photovoltaic aperture layer is arranged on an outer surface of the first panel.

6. The display device of claim 4, wherein:
the array of display elements is arranged between the first panel and the second panel on an outer surface of the second panel; and
the photovoltaic aperture layer is arranged on the inner surface of the first panel.

7. The display device of claim 4, wherein the array of display elements is arranged between the first panel and the second panel, each display element being configured to modulate light passage into the first panel from the second panel.

8. The display device of claim 4, further comprising a second aperture layer on an outer surface of the second panel.

9. The display device of claim 8, wherein an inner surface of the photovoltaic aperture layer is reflective to the modulated light from the display elements.

10. The display device of claim 1, further comprising a controller configured to:
analyze power signals received from the photovoltaic aperture layer via the conductive leads; and
manage power consumption of the device based on an amount or rate of power generated by the photovoltaic aperture layer.

11. The display device of claim 10, wherein the controller is further configured to modify an operation of the device based on the amount or rate of power generated by the photovoltaic aperture layer.

12. The display device of claim 1, further comprising a controller configured to:
analyze power signals received from the photovoltaic aperture layer via the conductive leads; and
determine the occurrences of touches or gestures based on the analyzed power signals.

13. The display device of claim 1, wherein a ratio of the surface area of the photovoltaic aperture layer not occupied by the apertures to the total surface area occupied by the photovoltaic aperture layer as a whole is greater than or equal to approximately 70%.

14. The display device of claim 1, wherein the photovoltaic aperture layer extends into a bezel region of the device beyond an active portion of the device that includes the display elements.

15. The display device of claim 1, further comprising:
a processor capable of processing image data; and
a memory device capable of communicating with the processor.

16. The display device of claim 15, further comprising:
a driver circuit capable of sending at least one signal to the display elements; and
a controller capable of sending at least a portion of the image data to the driver circuit.

17. The display device of claim 15, further comprising an image source module capable of sending the image data to the processor, wherein the image source module includes at least one of a receiver, transceiver, and transmitter.

18. The display device of claim 15, further comprising an input device capable of receiving input data and communicating the input data to the processor.

19. A display device comprising:
a first transparent panel;
an array of shutter-based display means arranged adjacent the first panel, each shutter-based display means including at least one shutter and at least one actuation means for translating the shutter to modulate light;
a photovoltaic means arranged adjacent the first panel for generating photovoltaic power, the photovoltaic means including an array of apertures, each aperture allowing light from a corresponding shutter-based display means to pass through the photovoltaic means for display; and
an array of conductive means for receiving photovoltaic power generated from the photovoltaic means.

20. The display device of claim 19, further comprising a controlling means for:
analyzing power signals received from the photovoltaic means via the conductive means; and
managing power consumption of the device based on an amount or rate of power generated by the photovoltaic means.

21. The display device of claim 20, wherein the controlling means is further for modifying an operation of the device based on the amount or rate of power generated by the photovoltaic means.

22. The display device of claim 19, further comprising a controlling means for:
analyzing power signals received from the photovoltaic means via the conductive means; and
determining the occurrences of touches or gestures based on the analyzed power signals.

23. The display device of claim 19, wherein a ratio of the surface area of the photovoltaic means not occupied by the apertures to the total surface area occupied by the photovoltaic means as a whole is greater than or equal to approximately 70%.
